(19) United States
(12) Patent Application Publication
(10) Pub. No.: US 2025/0332820 A1
(43) Pub. Date: Oct. 30, 2025

(54) PROTECTIVE FILM AND DISPLAY DEVICE INCLUDING THE SAME

(71) Applicant: SAMSUNG ELECTRONICS CO., LTD., Suwon-si (KR)

(72) Inventors: Su Jin SUNG, Yongin-si (KR); Jae Sul AN, Yongin-si (KR); Min-Gwan HYUN, Yongin-si (KR)

(21) Appl. No.: 18/974,856

(22) Filed: Dec. 10, 2024

(30) Foreign Application Priority Data
Apr. 24, 2024 (KR) 10-2024-0054956

(51) Int. Cl. B32B 27/08; B32B 7/02; B32B 7/12; G02F 1/1335; H10K 59/80

(52) U.S. Cl. CPC B32B 27/08; B32B 7/02; B32B 7/12; B32B 2255/10; B32B 2255/28; B32B 2307/40; B32B 2307/7376; B32B 2457/20; G02F 1/133502; G02F 2201/503; G02F 2202/28; H10K 59/873

(57) ABSTRACT

A protective film includes a plurality of support layers to be stacked, a hard coating layer disposed on an uppermost support layer among the plurality of support layers, and an anti-reflection layer disposed on the hard coating layer, wherein the plurality of support layers include resin layers each including a polymer resin, and adhesive layers contacting the resin layers and adhering the adjacent resin layers to each other, wherein the thicknesses of the plurality of support layers become thinner from a lowermost support layer to the uppermost support layer.

This application claims priority to Korean Patent Application No. 10-2024-0054956, filed on Apr. 24, 2024, and all the benefits accruing therefrom under 35 U.S.C. § 119, the content of which in its entirety is herein incorporated by reference.

### BACKGROUND

### 1. Field

The present invention relates to a protective film and a display device including the same, and more particularly, to a protective film covering and protecting a display surface of a display device and the display device including the same.

### 2. Description of the Related Art

A display device is a device for displaying an image on a screen, and includes a liquid crystal display (LCD), an organic light emitting diode (OLED), etc. Such a display device is used in various electronic devices such as a mobile phone, a navigation device, a digital camera, an electronic book, a portable game machine, or various terminals. A protective film for protecting a display surface of the display device from the outside is attached to the display surface of the display device.

### SUMMARY

Embodiments of the invention provide a protective film capable of preventing cracks during folding and a display device including the same. A protective film, according to an embodiment, includes a plurality of support layers to be stacked, a hard coating layer disposed on an uppermost support layer among the plurality of support layers, and an anti-reflection layer disposed on the hard coating layer, wherein the plurality of support layers include resin layers where each of the resin layers includes a polymer resin, and adhesive layers, where the adhesive layers contact the resin layers and adhere the adjacent resin layers to each other, where thicknesses of the plurality of support layers are thinner from a lowermost support layer to the uppermost support layer.

In an embodiment, thicknesses of the resin layers may be greater than thicknesses of the adhesive layers.

In an embodiment, the thicknesses of the adhesive layers of the support layers may be the same as each other.

In an embodiment, the resin layers may include at least one polymer resin selected from the group consisting of polyethylene terephthalate (PET), polyester, polyethylene, polypropylene, polydimethylsiloxane (PDMS), poly-4-vinylphenol, polymethyl methacrylate, polyvinylidene fluoride, polystyrene, polycarbonate, polyimide (PI), cellulose, polyvinyl chloride, polytetrafluoroethylene, polyvinyl alcohol, and polyurethane (PU).

In an embodiment, the adhesive layers may include a transparent pressure sensitive adhesive (PSA).

In an embodiment, the hard coating layer may include at least one selected from the group consisting of an organic material including a polyurethane resin, an acrylate resin, a urethane acrylate resin, a methacrylate resin, a silicon acrylate resin, an epoxy acrylate resin, an epoxy-based resin, or a silicon resin, an inorganic material including an oxide such as ZrO2, SiO2, or Al2O3, a nanocomposite such as hydroxyapatite coated AF (HACAF) or HA-bentonite coated AF (HABCAF), and a silicon-based organic-inorganic hybrid hard coating material.

In an embodiment, the plurality of support layers may include a first support layer contacting the hard coating layer and the second support layer disposed below the first support layer, wherein the first support layer may include a first resin layer and a first adhesive layer, the second support layer may include a second resin layer and a second adhesive layer, where a thickness of the first resin layer may be lesser than a thickness of the second resin layer.

In an embodiment, the thickness of the first resin layer may be greater than a thickness of the first adhesive layer.

In an embodiment, the thickness of the second resin layer may be greater than a thickness of the second adhesive layer.

In an embodiment, a thickness of the first adhesive layer and the thickness of the second adhesive layer may be the same as each other.

A display device, according to an embodiment, includes a display panel displaying an image and a protective film disposed on a display surface displaying the image on the display panel, wherein the protective film includes a plurality of support layers to be stacked, and a hard coating layer disposed on an uppermost support layer among the plurality of support layers, wherein the plurality of support layers include resin layers, each of the resin layers including a polymer resin, and adhesive layers contacting the resin layers and adhering the adjacent resin layers to each other, where thicknesses of the plurality of support layers are thinner from a lowermost support layer to the uppermost support layer.

According to an embodiment, when the protective film is folded, the amount of strain occurring on the upper surface of the hard coating layer may be minimized, thereby preventing cracks from occurring in the anti-reflection layer contacting the upper surface of the hard coating layer.

### BRIEF DESCRIPTION OF THE DRAWINGS

FIG. 1 is a schematic cross-sectional view of a protective film, according to an embodiment.

FIG. 2 is a schematic cross-sectional view of a display device including the protective film of FIG. 1, according to an embodiment.

FIG. 3 is a schematic cross-sectional view of a protective film, according to another embodiment.

FIG. 4 is a schematic cross-sectional view of a display device including the protective film of FIG. 3, according to an embodiment.

### DETAILED DESCRIPTION

With reference to the attached drawings, embodiments of the invention will be described in detail so that those with ordinary skilled in the art may easily implement the invention. The invention may be embodied in many different forms and is not limited to the embodiments set forth herein.

In order to clearly explain the invention in the drawings, parts irrelevant to the description are omitted, and the same reference numerals are used for the same or similar elements throughout the specification.

In addition, since the size and thickness of each component shown in the drawings are arbitrarily shown for convenience of description, the invention is not limited to those shown. In the drawings, the thickness of layers and regions are exaggerated for clarity.

In addition, in the drawings, for convenience of explanation, thicknesses of some layers and areas are exaggerated. In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “above” or “on” a reference part means being above or below the reference part and does not necessarily mean being “above” or “on” in the opposite direction of gravity.

In addition, throughout the specification, unless explicitly described to the contrary, the word “comprise”, and variations such as “comprises” or “comprising”, will be understood to imply the inclusion of stated elements but not the exclusion of any other elements.

In addition, throughout the specification, when it is “on a plane” means when a target portion is viewed from above, and when it is “on a cross section” means when a cross section obtained by vertically cutting a target portion is viewed from the side.

When a part of a layer, membrane, region, or plate, is said to be “above” or “on” another part, this includes not only being “directly on” another component, but also having another component in between. Conversely, when a composition is said to be “right above” another composition, it means that there is no other composition in between. Throughout the specification, it means that a certain part may further include other components, unless there is a statement to the contrary that it “includes” a certain component.

Throughout the specification, “connected” does not mean only when two or more components are directly connected, but when two or more components are indirectly connected through other components, when they are physically connected, or when they are electrically connected, it may include embodiments where each part, which may be referred to by a different name depending on location or function, but is substantially integrated, is connected to another.

In the drawings, the symbols “X”, “Y”, and “Z” are used to indicate directions, where “X” is a first direction, “Y” is a second direction perpendicular to the first direction, and “Z” is a third direction perpendicular to the first and second directions.

Then, a display device, according to an embodiment, will be described in detail with reference to the drawings.

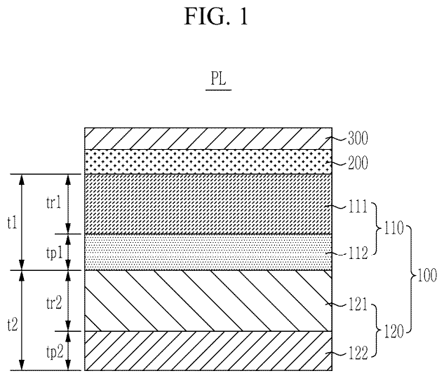

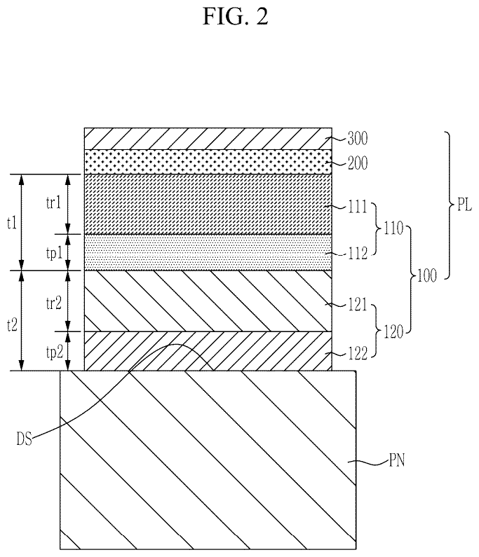

FIG. 1 is a schematic cross-sectional view of a protective film, according to an embodiment. FIG. 2 is a schematic cross-sectional view of a display device including the protective film of FIG. 1, according to an embodiment.

As shown in FIGS. 1 and 2, the display device, according to an embodiment, includes a display panel PN and a protective film PL.

The display panel PN is a device for displaying an image, and may include a liquid crystal display panel, an organic light emitting display panel, etc.

The protective film PL may be disposed on a display surface DS displaying an image on the display panel PN to protect the display panel PN from the outside.

In an embodiment, the protective film PL includes a plurality of support layers 100, a hard coating layer 200, and an anti-reflection layer 300.

In an embodiment, the plurality of support layers 100 may include a first support layer 110 contacting the hard coating layer 200 and a second support layer 120 disposed below the first support layer 110.

The first support layer 110 may include a first resin layer 111 and a first adhesive layer 112, and the second support layer 120 may include a second resin layer 121 and a second adhesive layer 122.

The first resin layer 111 and the second resin layer 121 may each include a transparent polymer resin. For example, in an embodiment, the first resin layer 111 and the second resin layer 121 may include at least one polymer resin selected from the group consisting of polyethylene terephthalate (PET), polyester, polyethylene, polypropylene, polydimethylsiloxane (PDMS), poly-4-vinylphenol, polymethyl methacrylate, polyvinylidene fluoride, polystyrene, polycarbonate, polyimide (PI), cellulose, polyvinyl chloride, polytetrafluoroethylene, polyvinyl alcohol, and polyurethane (PU). Therefore, the first resin layer 111 and the second resin layer 121 may have flexible characteristics.

Table 1 below shows an amount S of strain occurring on an upper surface of the hard coating layer 200 when the protective film PL is folded at a radius of curvature of about 1.5 according to a thickness tr1 of the first resin layer 111, a thickness tr2 of the second resin layer 121, a thickness tp1 of the first adhesive layer 112, and a thickness tp2 of the second adhesive layer 122 of the protective film, according to an embodiment, and shows a Comparative Example and Experimental Examples 1 to 10.

TABLE 1

| | Com- | Experi- | Experi- | Experi- | Experi- | Experi- | Experi- | Experi- | Experi- | Experi- | Experi- |
|---|---|---|---|---|---|---|---|---|---|---|---|
| | parative | mental | mental | mental | mental | mental | mental | mental | mental | mental | mental |
| | Example | Example1 | Example2 | Example3 | Example4 | Example5 | Example6 | Example7 | Example8 | Example9 | Example10 |
| tr1(um) | 100 um | 20 um | 20 um | 20 um | 50 um | 80 um | 30 um | 40 um | 70 um | 60 um | 20 um |
| tp1(um) | 25 um | 10 um | 25 um | 50 um | 25 um | 25 um | 25 um | 25 um | 25 um | 25 um | 25 um |
| tr2(um) | — | 80 um | 80 um | 80 um | 50 um | 20 um | 70 um | 60 um | 30 um | 40 um | 55 um |
| tp2(um) | — | 25 um | 25 um | 25 um | 25 um | 25 um | 25 um | 25 um | 25 um | 25 um | 25 um |
| S (%) | −5.150 | −2.926 | −2.332 | delamination | −3.154 | −4.294 | −2.565 | −2.843 | −3.895 | −3.509 | −2.147 |

As shown in Table 1, in the case of the Comparative Example including only the first resin layer 111 and the second resin layer 121, it may be seen that the amount S of the strain occurring on the upper surface of the hard coating layer 200 is very high at about 5.15%.

As in an embodiment, in the case of Experimental Examples 1 to 10 including the first resin layer 111, the first adhesive layer 112, the second resin layer 121, and the second adhesive layer 122, it may be seen that the amount S of the strain occurring on the upper surface of the hard coating layer 200 is lower than that of the Comparative Example.

In an embodiment and as shown in Table 1, it may be seen that in the case of the Experimental Examples 1, 2, 6, 7, and 10 in which the thickness tr1 of the first resin layer 111 is lesser than the thickness tr2 of the second resin layer 121, the amount S of the strain occurring on the upper surface of the hard coating layer 200 is about −2%, which is lower than in the case of Experimental Examples 4, 5, 8, and 9 in which the thickness tr1 of the first resin layer 111 is greater than or equal to the thickness tr2 of the second resin layer 121.

In an embodiment, the thickness tr1 of the first resin layer 111 may be lesser than the thickness tr2 of the second resin layer 121. As described above, in an embodiment, in which the protective film PL includes the plurality of support layers 100, and the thickness tr1 of the first resin layer 111 is lesser than the thickness tr2 of the second resin layer 121, when the protective film PL is folded, the amount S of the strain occurring on the upper surface of the hard coating layer 200 may be minimized, thereby preventing cracks from occurring on the anti-reflection layer 300 contacting the upper surface of the hard coating layer 200.

In an embodiment, the first adhesive layer 112 may be disposed between the first resin layer 111 and the second resin layer 121 to attach the first resin layer 111 and the second resin layer 121 to each other. The second adhesive layer 122 may be disposed below the second resin layer 121 to attach the second resin layer 121 to an external object such as the display panel PN.

In an embodiment, the first adhesive layer 112 and the second adhesive layer 122 may include a transparent pressure sensitive adhesive (PSA), etc. The PSA may exhibit viscoelasticity while maintaining a semi-solid shape before and after attachment. Therefore, when the first resin layer 111 and the second resin layer 121 are attached to each other or the second resin layer 121 is attached to the display panel PN, the flexible characteristics of the first resin layer 111 and the second resin layer 121 may be maintained as they are.

In an embodiment and as shown in Table 1, it may also be seen that as in the case of Experimental Examples 2, 6, 7, and 10 in which the thickness tr1 of the first resin layer 111 is lesser than the thickness tr2 of the second resin layer 121, and the thickness tp1 of the first adhesive layer 112 and the thickness tp2 of the second adhesive layer 122 are the same, the amount S of the strain occurring on the upper surface of the hard coating layer 200 is lower than in the case of Experimental Example 1 in which the thickness tr1 of the first resin layer 111 is lesser than the thickness tr2 of the second resin layer 121, and the thickness tp1 of the first adhesive layer 112 and the thickness tp2 of the second adhesive layer 122 are not the same.

Accordingly, in an embodiment, the thickness tp1 of the first adhesive layer 112 and the thickness tp2 of the second adhesive layer 122 may be the same as each other. In an embodiment in which the thickness tp1 of the first adhesive layer 112 and the thickness tp2 of the second adhesive layer 122 may be the same as each other, when the protective film PL is folded, the size S of the strain occurring on the upper surface of the hard coating layer 200 may be minimized, thereby preventing cracks from occurring on the anti-reflection layer 300 contacting the upper surface of the hard coating layer 200.

In an embodiment, as shown in Experimental Example 3 of Table 1, when the thickness tp1 of the first adhesive layer 112 is greater than the thickness tr1 of the first resin layer 111, the first adhesive layer 112 is delaminated from the first resin layer 111.

Therefore, the thickness tr1 of the first resin layer 111 may be greater than the thickness tp1 of the first adhesive layer 112. Similarly, the thickness tr2 of the second resin layer 121 may be greater than the thickness tp2 of the second adhesive layer 122. As described above, by forming the thickness tr1 of the first resin layer 111 and the thickness tr2 of the second resin layer 121 to be greater than the thickness tp1 of the first adhesive layer 112 and the thickness tp2 of the second adhesive layer 122, when the protective film PL is folded, the adhesive layers 112 and 122 may be prevented from being delaminated from the resin layers 111 and 121, respectively.

In an embodiment, the hard coating layer 200 may be disposed on the first support layer 110, which is the uppermost support layer among the plurality of support layers 100. The hard coating layer 200 may have a high light transmittance of about 80% or more and a high hardness of about 8 H or more simultaneously. Here, H is a unit of measuring pencil hardness. The hard coating layer 200 has a thickness of about 5 μm to about 70 μm, thereby implementing flexible performance.

In an embodiment, the hard coating layer 200 may include at least one selected from the group consisting of an organic material such as a polyurethane resin, an acrylate resin, a urethane acrylate resin, a methacrylate resin, a silicon acrylate resin, an epoxy acrylate resin, an epoxy-based resin, or a silicon resin, an inorganic material including an oxide such as ZrO2, SiO2, or Al2O3, a nanocomposite such as hydroxyapatite coated AF (HACAF) or HA-bentonite coated AF (HABCAF), and a silicon-based organic-inorganic hybrid hard coating material.

In an embodiment, the anti-reflection layer 300 may be disposed on the hard coating layer 200, where the anti-reflection layer 300 may reduce reflectance by coating at least one thin film on a substrate so that external light is extinguished through offset interference. The anti-reflection layer 300 may adjust the reflectance by adjusting the thickness and refractive index of the thin film.

In an embodiment and as described above, in the protective film PL, the hard coating layer 200 and the anti-reflection layer 300 are sequentially stacked on the plurality of support layers 100, where the plurality of support layers 100 are formed as the first support layer 110 contacting the hard coating layer 200, and the second support layer 120 is disposed below the first support layer 110, and where the thickness of the first resin layer 111 of the first support layer 110 is lesser than the thickness of the second resin layer 121 of the second support layer 120. Thus, when the protective film PL is folded, the amount S of the strain occurring on the upper surface of the hard coating layer 200 may be minimized, thereby preventing cracks from occurring on the anti-reflection layer 300 contacting the upper surface of the hard coating layer 200.

In the above embodiment, a plurality of support layers 100 includes a first support layer 110 and a second support layer 120, but another embodiment in which a plurality of support layers includes three or more layers is possible.

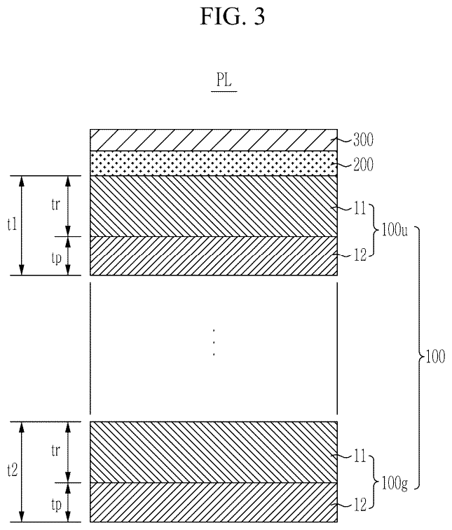

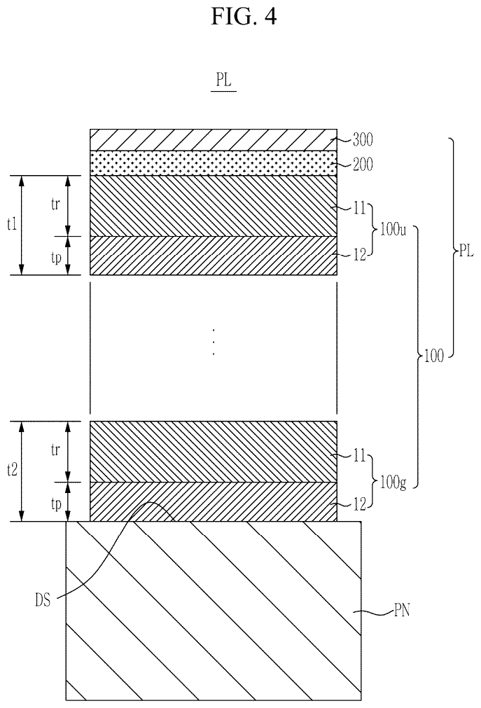

Hereinafter, a display device, according to another embodiment, will be described in detail with reference to FIGS. 3 and 4.

FIG. 3 is a schematic cross-sectional view of a protective film, according to an embodiment. FIG. 4 is a schematic cross-sectional view of a display device including the protective film of FIG. 3, according to an embodiment.

An embodiment shown in FIGS. 3 and 4 is substantially the same as an embodiment shown in FIGS. 1 and 2, with the exception of a structure of a support layer, and thus, the repeated descriptions thereof are omitted.

In an embodiment and as shown in FIGS. 3 and 4, a display device includes the display panel PN and the protective film PL.

In an embodiment, the protective film PL includes the plurality of support layers 100, the hard coating layer 200, and the anti-reflection layer 300, where the plurality of support layers 100 may be stacked.

In an embodiment, the plurality of support layers 100 may include at least three support layers 100. Thicknesses t of the plurality of support layers 100 may be thinner from a lowermost support layer 100g to an uppermost support layer 100u. That is, the first thickness t1, which is the thickness of the uppermost support layer 100u, may be less than the second thickness t2, which is the thickness of the lowermost support layer 100g.

As described above, the protective film PL, according to an embodiment, includes the plurality of support layers 100, where the thicknesses t of the plurality of support layers 100 are thinner from the lowermost support layer 100g to the uppermost support layer 100u. When the protective film PL is folded, the amount of a strain occurring on an upper surface of the hard coating layer 200 may be minimized, thereby preventing cracks from occurring in the anti-reflection layer 300 contacting the upper surface of the hard coating layer 200.

In an embodiment, each support layer 100 may include a resin layer 11 and an adhesive layer 12, where the resin layer 11 may include a transparent polymer resin. Therefore, the resin layer 11 may have flexible characteristics.

The adhesive layer 12 may contact the resin layer 11 and adhere adjacent resin layers 11 to each other or adhere the resin layer 11 to a display surface of the display panel PN.

In an embodiment, the adhesive layer 12 may include a transparent PSA, etc., where the PSA may exhibit viscoelasticity while maintaining a semi-solid shape before and after attachment.

Accordingly, when the adjacent resin layers 11 are attached to each other or the resin layer 11 is attached to the display panel PN, the flexible characteristics of the resin layer 11 may be maintained as they are.

In an embodiment, the thickness of each adhesive layer 12 may be the same as each other. In an embodiment in which a thickness tp of each adhesive layer 12 is the same, when the protective film PL is folded, the amount of the strain occurring on the upper surface of the hard coating layer 200 may be minimized, thereby preventing cracks from occurring on the anti-reflection layer 300 contacting the upper surface of the hard coating layer 200.

In an embodiment, a thickness tr of the resin layer 11 may be greater than the thickness tp of the adhesive layer 12. As described above, by forming the thickness tr of the resin layer 11 to be greater than the thickness tp of the adhesive layer 12, the adhesive layer 12 is prevented from being delaminated from the resin layer 11, when the protective film PL is folded.

In an embodiment, the hard coating layer 200 may be disposed on the uppermost support layer 100u among the plurality of support layers 100, and the anti-reflection layer 300 may be disposed on the hard coating layer 200.

Although embodiments of the invention have been described in detail above, the scope of the invention is not limited thereto, and various modifications and improvements made by those of ordinary skill in the art to which the invention pertains. Therefore, the scope of the invention is not limited to the contents described in the detailed description. Moreover, the embodiments or parts of the embodiments may be combined in whole or in part without departing from the scope of the invention.

What is claimed is:

1. A protective film comprising:
a plurality of support layers to be stacked, wherein each of the plurality of support layers include a thickness;
a hard coating layer disposed on an uppermost support layer among the plurality of support layers; and
an anti-reflection layer disposed on the hard coating layer,
wherein the plurality of support layers include
resin layers, wherein each of the resin layers include a polymer resin; and
adhesive layers contacting the resin layers, wherein the adhesive layers adhere adjacent resin layers to each other, wherein
thicknesses of the plurality of support layers become thinner from a lowermost support layer to the uppermost support layer.

2. The protective film of claim 1, wherein:
thicknesses of the resin layers are greater than thicknesses of the adhesive layers.

3. The protective film of claim 2, wherein:
the thicknesses of the adhesive layers of the support layers are the same as each other.

4. The protective film of claim 1, wherein:
the resin layers include at least one polymer resin selected from the group consisting of polyethylene terephthalate (PET), polyester, polyethylene, polypropylene, polydimethylsiloxane (PDMS), poly-4-vinylphenol, polymethyl methacrylate, polyvinylidene fluoride, polystyrene, polycarbonate, polyimide (PI), cellulose, polyvinyl chloride, polytetrafluoroethylene, polyvinyl alcohol, and polyurethane (PU).

5. The protective film of claim 1, wherein:
the adhesive layers include a transparent pressure sensitive adhesive (PSA).

6. The protective film of claim 1, wherein:
the hard coating layer includes at least one selected from the group consisting of
an organic material including a polyurethane resin, an acrylate resin, a urethane acrylate resin, a methacrylate resin, a silicon acrylate resin, an epoxy acrylate resin, an epoxy-based resin, or a silicon resin,
an inorganic material including an oxide such as ZrO2, SiO2, or Al2O3, a nanocomposite such as hydroxyapatite coated AF (HACAF) or HA-bentonite coated AF (HABCAF), and
a silicon-based organic-inorganic hybrid hard coating material.

7. The protective film of claim 1, wherein:
the plurality of support layers include
a first support layer contacting the hard coating layer; and
the second support layer disposed below the first support layer, wherein
the first support layer includes a first resin layer and a first adhesive layer, and
the second support layer includes a second resin layer and a second adhesive layer, where
a thickness of the first resin layer is lesser than a thickness of the second resin layer.

8. The protective film of claim 7, wherein:
the thickness of the first resin layer is greater than a thickness of the first adhesive layer.

9. The protective film of claim 8, wherein:
the thickness of the second resin layer is greater than a thickness of the second adhesive layer.

10. The protective film of claim 7, wherein:
a thickness of a first adhesive layer and a thickness of the second adhesive layer are the same as each other.

11. A display device comprising:
a display panel displaying an image; and
a protective film disposed on a display surface on the display panel,
wherein the protective film includes
a plurality of support layers to be stacked; and
a hard coating layer disposed on an uppermost support layer among the plurality of support layers,
wherein the plurality of support layers include
resin layers, wherein each of the resin layers include a polymer resin; and
adhesive layers contacting the resin layers, wherein the adhesive layers adhere adjacent resin layers to each other, wherein
thicknesses of the plurality of support layers become thinner from a lowermost support layer to the uppermost support layer.

12. The display device of claim 11, wherein:
thicknesses of the resin layers are greater than thicknesses of the adhesive layers.

13. The display device of claim 12, wherein:
the thicknesses of the adhesive layers are the same.

14. The display device of claim 11, wherein:
the resin layers include at least one polymer resin selected from the group consisting of polyethylene terephthalate (PET), polyester, polyethylene, polypropylene, polydimethylsiloxane (PDMS), poly-4-vinylphenol, polymethyl methacrylate, polyvinylidene fluoride, polystyrene, polycarbonate, polyimide (PI), cellulose, polyvinyl chloride, polytetrafluoroethylene, polyvinyl alcohol, and polyurethane (PU).

15. The display device of claim 11, wherein:
the adhesive layers include a transparent pressure sensitive adhesive (PSA).

16. The display device of claim 11, wherein:
the hard coating layer includes at least one selected from the group consisting of
an organic material including a polyurethane resin, an acrylate resin, a urethane acrylate resin, a methacrylate resin, a silicon acrylate resin, an epoxy acrylate resin, an epoxy-based resin, or a silicon resin,
an inorganic material including an oxide such as ZrO2, SiO2, or Al2O3, a nanocomposite such as hydroxyapatite coated AF (HACAF) or HA-bentonite coated AF (HABCAF), and
a silicon-based organic-inorganic hybrid hard coating material.

17. The display device of claim 11, wherein:
the plurality of support layers include
a first support layer contacting the hard coating layer; and
the second support layer disposed below the first support layer, wherein
the first support layer includes a first resin layer and a first adhesive layer, and
the second support layer includes a second resin layer and a second adhesive layer, wherein
a thickness of the first resin layer is lesser than a thickness of the second resin layer.

18. The display device of claim 17, wherein:
the thickness of the first resin layer is greater than a thickness of the first adhesive layer.

19. The display device of claim 18, wherein:
the thickness of the second resin layer is greater than a thickness of the second adhesive layer.

20. The display device of claim 17, wherein:
a thickness of the first adhesive layer and a thickness of the second adhesive layer are the same.
